(19) United States
(12) Patent Application Publication
(10) Pub. No.: US 2002/0197416 A1
(43) Pub. Date: Dec. 26, 2002

(54) Gas jet deposition with multiple ports

(76) Inventors: Robert B. Majewski, Watsonville, CA (US); Alain Duboust, Sunnyvale, CA (US); Gang Chen, Union City, CA (US); Sean Li, Sunnyvale, CA (US); Jallepally Ravi, Santa Clara, CA (US); Liang-Yuh Chen, Foster City, CA (US); Daniel Carl, Pleasanton, CA (US)

Correspondence Address: APPLIED MATERIALS, INC., 2881 SCOTT BLVD. M/S 2061, SANTA CLARA, CA, 95050, US

(21) Appl. No.: 09/887,248

(22) Filed: Jun. 21, 2001

(51) Int. Cl. C23C 16/00

(52) U.S. Cl. 427/569; 118/723 ME

(57) ABSTRACT

A gas jet deposition method and apparatus includes a plurality of ports to supply plasma to the substrate on which deposition is to occur. A reagent gas is introduced either into the ports or into the expansion chamber. The use of multiple ports results in a much more uniform deposition of material on the substrate. In preferred embodiments, a carrier gas plasma is created using an excitation source such as a microwave power supply.

### BACKGROUND OF THE INVENTION

1. Field of the Invention

The present invention relates to the field of thin film deposition generally, and more particularly to gas jet deposition of thin films.

2. Discussion of the Background

Depositing thin films of materials (including metals, semiconductors, insulators/dielectrics, organics and inorganics) is required in a wide variety of manufacturing operations. The semiconductor manufacturing industry is one industry in which thin film deposition is especially important. The present invention will therefore be discussed in connection with the semiconductor manufacturing industry, but it should be understood that the present invention is not limited thereto.

There are several known methods for depositing thin films. One such method is known as gas jet deposition. This method is desirable for many applications because it can be performed at low temperatures (less than 300 degrees Celsius). In gas jet deposition, a carrier gas is excited, typically by applying microwave power to the gas while it is in an applicator, such that a plasma is formed. The applicator feeds a chamber which is maintained at a lower pressure than the applicator. This pressure difference causes gases to exit the applicator at high speeds. A reagent gas is introduced near the exit of the applicator. This gas reacts with the carrier gas to form a deposition material. The deposition material is then deposited on a substrate that is positioned in the flow of the gases exiting from the applicator. An example of such a gas jet deposition system is discussed in U.S. Pat. No. 5,256,205.

An important problem with known jet deposition systems is that the thin film that is deposited is often not of uniform depth. Uniform depth is important in many applications, including especially the semiconductor manufacturing industry. Known gas jet deposition systems, such as the one described in U.S. Pat. No. 5,256,205, use a single jet in the deposition process. In a single jet, there is typically a greater flow in the center of the jet stream than at the edges of a jet stream due to friction of the gas with the side wall of the jet. This results in the aforementioned non-uniform deposition problem.

What is needed is a more uniform gas jet deposition technique.

### SUMMARY OF THE INVENTION

The present invention meets the foregoing need to a great extent by providing a gas jet deposition method and apparatus in which a plurality of ports supply gas to the substrate on which deposition is to occur. In preferred embodiments, a carrier gas plasma is created using an excitation source such as a microwave power supply. The applicator is in fluid communication with an expansion chamber. The carrier gas plasma, which is at a high pressure, exits the applicator and enters the expansion chamber, which is at a relatively lower pressure. In a wall of the expansion chamber opposite the applicator are formed a plurality of orifices, which are in fluid communication with a deposition chamber. Near the orifices is a reagent gas source which supplies a reagent gas. The carrier gas and the second gas react to form the material that is ultimately deposited. The carrier gas passes through the ports and enters the deposition chamber, which is maintained at a lower pressure than both the expansion chamber and the applicator. The deposition material is eventually deposited on a substrate in the deposition chamber. The use of multiple ports results in a much more uniform deposition of material on the substrate.

### BRIEF DESCRIPTION OF THE DRAWINGS

A more complete appreciation of the invention and many of the attendant advantages and features thereof will be readily obtained as the same becomes better understood by reference to the following detailed description when considered in connection with the accompanying drawings, wherein:

FIG. 1 is a cross sectional view of a gas jet deposition apparatus according to a first embodiment of the present invention.

FIG. 2 is a cross sectional view of a plate from the apparatus of FIG. 1 having a plurality of orifices formed therein.

FIG. 3 is a cross sectional view of a gas jet deposition apparatus according to a second embodiment of the present invention.

FIGS. 4a,b are perspective and cross sectional views, respectively, of a port included in the embodiment of FIG. 3.

### DESCRIPTION OF PREFERRED EMBODIMENTS

The present invention will be discussed with reference to preferred embodiments of gas jet deposition devices. Specific details, such as dimensions of ports and chambers, are set forth in order to provide a thorough understanding of the present invention. The preferred embodiments discussed herein should not be understood to limit the invention. Furthermore, for ease of understanding, certain method steps are delineated as separate steps; however, these steps should not be construed as necessarily distinct nor order dependent in their performance.

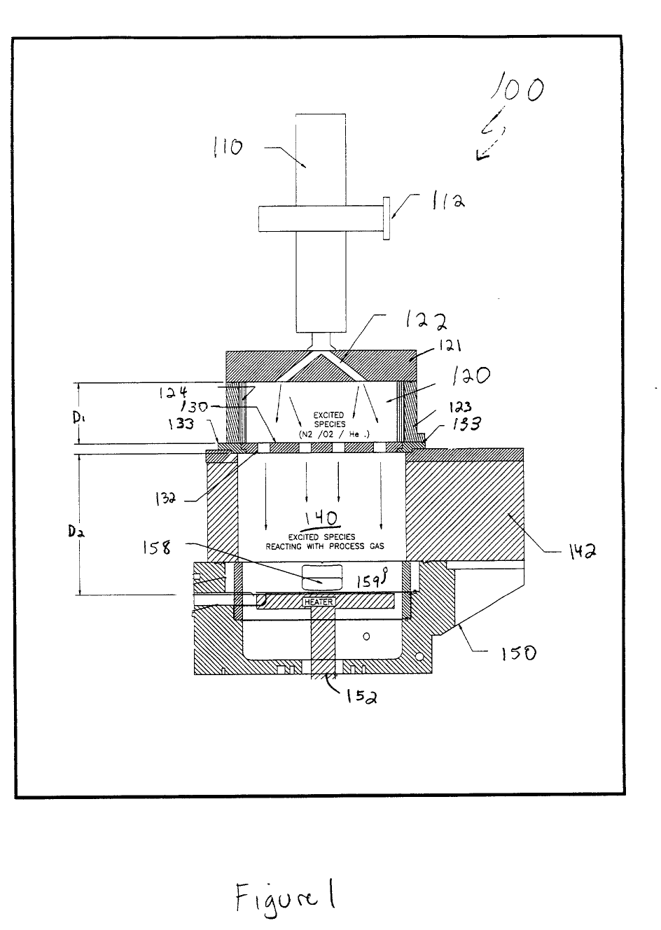

FIG. 1 illustrates a gas deposition apparatus 100. The apparatus 100 includes an applicator 110 to which is attached a waveguide 112. The waveguide 112 is connected to a microwave power supply (not shown in FIG. 1). Microwave energy supplied through the waveguide 112 excites a gas (e.g., nitrogen, to which a second gas such as helium may be added to increase gas diffusivity) in the applicator 110, thereby forming a plasma. Preferably, a pressure in the applicator 110 is between 0.5 torr and 10 torr.

The plasma is transported to an expansion chamber 120 through a plurality of channels 122 formed in an expansion chamber lid 121. The expansion chamber includes a sidewall 123 which typically includes a quartz liner 124. The pressure in the expansion chamber 120 is less than the pressure in the applicator 110, and is preferably between 0.1 and 2 torr. This pressure difference causes plasma from the applicator 110 to exit the channels 122 at high speeds (however, unlike the apparatus discussed in U.S. Pat. No. 5,256,205, these speeds are subsonic).

The plasma exits the expansion chamber 120 through a plurality of ports 132 in an expansion chamber floor 130. The floor 130 is supported by an adapter ring 133. Each of the ports 132 in the floor 130 is preferably approximately one inch in diameter. A distance D₁ from the expansion chamber top 121 and the floor 130 is 5-25 cm in preferred embodiments.

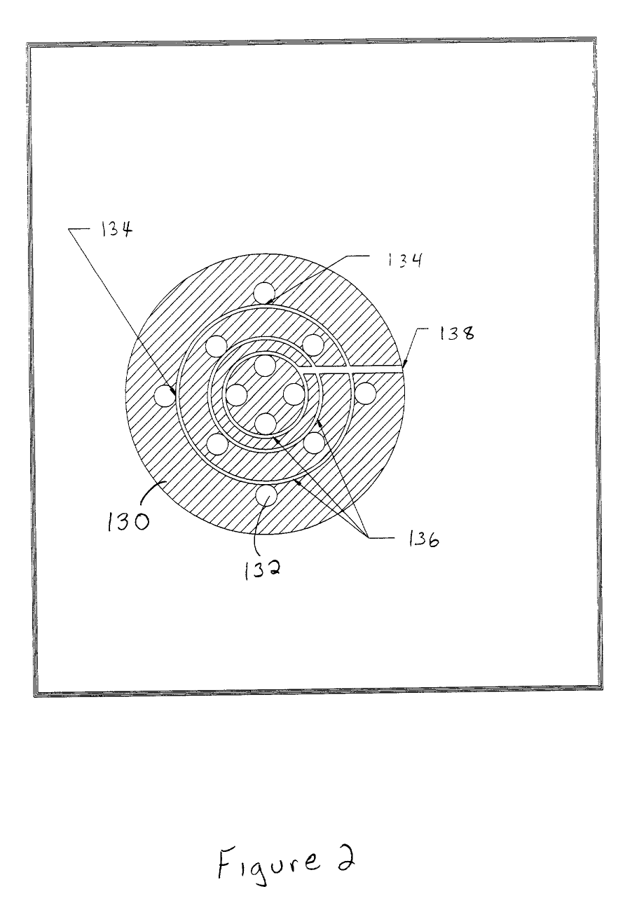

The cross-sectional view of FIG. 2 illustrates the floor 130 in greater detail. Each of the ports 132 has an orifice 134 formed through a sidewall of the port 132 such that each of the ports 132 is in fluid communication with one of a plurality of gas distribution rings 136. The gas distribution rings 136 are connected to and in fluid communication with a gas supply line 138. The floor 130 may be made of a material such as aluminum. In order to fabricate the floor 130, the gas distribution rings 136 and the supply line 138 are formed on an upper surface of an aluminum disc using a router. Next, the ports 132 are formed. Then an orifice 134 is formed in each port 132 to connect the port 132 to a gas distribution ring 136. Next, a second aluminum disc is placed over the first disc with a metal flux between the first and second discs. The two discs are then placed in a vacuum autoclave and heated until the metal flux melts, thereby binding the two discs together to form the floor 130.

The gas supply line 138 is connected to a reagent gas. In this fashion, the reagent gas is mixed with the plasma as it passes through the ports 122. The plasma and reagent react to form a deposition material. It is possible to form many different deposition materials in this fashion. By way of example, silane reagent gas could be used together with a plasma formed from a nitrogen/helium gas mixture to form a deposition material such as silicon nitride (Si₃N₄). Although the ports 132 are illustrated as having a circular cross-sectional shape in FIGS. 1 and 2, other cross-sectional shapes, including, but not limited to, square, hexagonal, and oval may be used. Furthermore, the pattern of ports 132 may be different from that shown in FIG. 2. For example, in another embodiment, the innermost four ports 132 may be replaced by a single port 132 of the same size so that 3×3 grid of ports 132 is formed. In yet another embodiment, ports 132 in addition to the ports 132 of FIG. 2 are added to the floor 130.

Referring now back to FIG. 1, the plasma and reagent gases and products formed by the reaction between the two exit the ports 132 and enter a deposition chamber 140. Material formed by the reaction (e.g., silicon nitride) is deposited onto a substrate on a platform 152. Gases and undeposited material are removed through a plurality of vents 159 (only one is shown in FIG. 1) that are provided around the walls of the chamber 150. The vents 159 are in fluid communication with a pumping port 158, which is connected to a vacuum pump. It has been discovered that adjusting the height of the platform 152 such that it is just below the vents 159 provides superior performance. The provision of the multiple ports 132 results in an improved uniformity of distribution as compared to single port deposition devices.

A distance D₂ in FIG. 1, which is the distance between the bottom of floor 130 and the top of platform 152, is chosen (by adding spacer 142) to provide uniform deposition. In preferred embodiments, this distance is between approximately 10 centimeters and approximately 60 centimeters. In some embodiments, the platform 152 is stationary; in other embodiments, the platform is rotated to improve deposition uniformity.

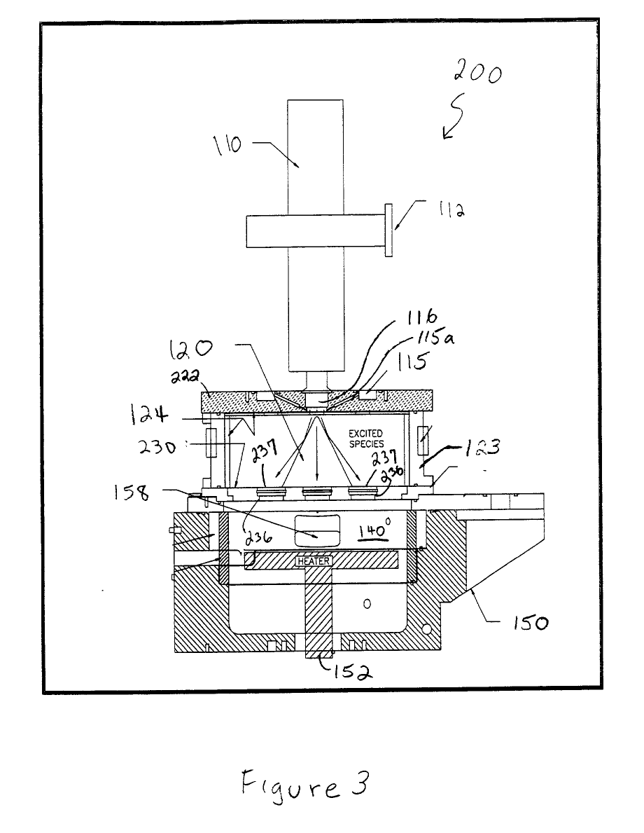

A second embodiment of the invention is illustrated by the device 200 shown in FIG. 3. In this embodiment, microwave energy from a waveguide 112 energizes a gas in an applicator 110 to create a plasma. The plasma passes through a port 116 in a lid 222 of an expansion chamber 120. In this embodiment, the reagent gas is drawn from a reservoir 115 into plasma stream through supply tubes 115a. The reagent gas and the carrier gas from the applicator 110 are thus combined in the expansion chamber 120 prior to their passage through the floor 230.

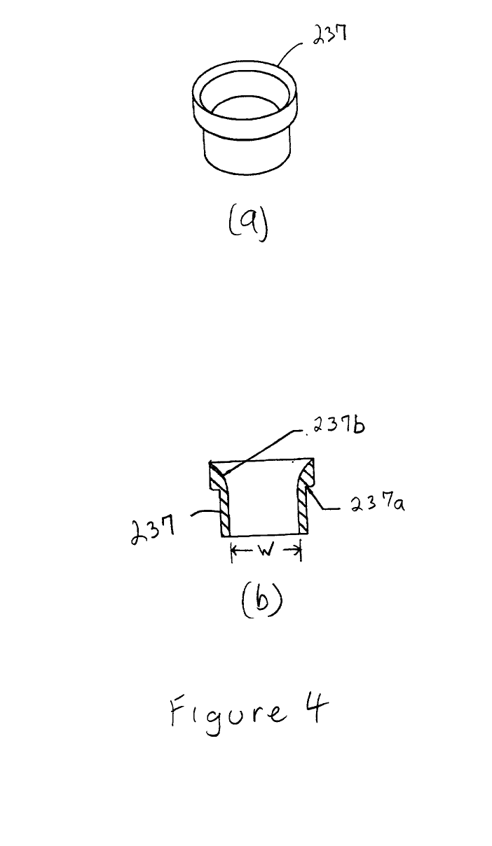

Inserted into openings 236 in the floor 230 are nozzles 237, as illustrated in FIG. 4. The nozzle 237 includes a shoulder 237a which rests on a corresponding notch in the floor 230 to support the nozzle 237. A nozzle opening 237b is tapered to a nozzle width W. In preferred embodiments, the width W ranges from approximately one-half of an inch to approximately one inch. The nozzles 237 serve the same function as the ports 132 of FIG. 1—namely, the nozzles 237 cause the gases from the expansion chamber 120 to be evenly distributed over the wafer on platform 152, thereby causing the deposition material to be evenly deposited.

Other embodiments of the invention that share some of the features of the foregoing embodiments are also possible. For example, the lid 222 of FIG. 3 (which includes the reservoirs 115 and passages 115a) could be used to replace the lid 122 in the embodiment of FIG. 1. In such an embodiment, the floor 130 is dramatically simplified by eliminating the gas distribution rings 136, supply line 138 and orifices 134. In other words, since the reagent gas is being supplied by the reservoirs in the lid 222, it is only necessary to form ports 132 in the floor 130. This simplification would make the use of a material such as quartz for the floor 130 practical economically.

Obviously, numerous other modifications and variations of the present invention are possible in light of the above teachings. It is therefore to be understood that within the scope of the appended claims, the invention may be practiced otherwise than as specifically described herein.

What is claimed is:

1. An apparatus for gas deposition comprising:
a plasma supply, the plasma supply having a first pressure;
an expansion chamber connected to the plasma supply, the expansion chamber being at a second pressure, the second pressure being lower than the first pressure, the expansion chamber having a plurality of ports formed therein;
a deposition chamber in fluid communication with the expansion chamber through the ports, the deposition chamber being at a third pressure, the third pressure being lower than the second pressure.

2. The apparatus of claim 1, further comprising a vacuum pump connected to the deposition chamber, the vacuum pump being operable to maintain the deposition chamber at the third pressure.

3. The apparatus of claim 1, wherein the plasma supply comprises an applicator, a gas supply connected to the applicator to supply a carrier gas to the applicator, and a microwave power supply configured to excite the carrier gas in the applicator to create a plasma.

4. The apparatus of claim 1, wherein the first pressure is between approximately one half torr and approximately ten torr, and the second pressure is between approximately 0.1 torr and approximately two torr.

5. The apparatus of claim 4, further including a pedestal for supporting a substrate, the pedestal having a substantially planar first surface, wherein the expansion chamber includes a substantially planar second surface and a distance between the first surface and the second surface is chosen to provide substantially uniform distribution.

6. The method of claim 5, wherein the distance between the first surface and the second surface is between approximately ten centimeters and approximately sixty centimeters.

7. The apparatus of claim 1, further comprising a supply of a reagent gas, the supply being connected to introduce reagent gas into each of the ports.

8. The apparatus of claim 7, wherein the reagent gas is introduced through an orifice in a side wall in each of the ports.

9. The apparatus of claim 3, further comprising a supply of a reagent gas, the supply being connected to introduce the reagent gas into the expansion chamber.

10. The apparatus of claim 9, wherein the supply includes a nozzle positioned in close proximity to an outlet of the applicator.

11. The apparatus of claim 1, wherein the expansion chamber is positioned above the deposition chamber.

12. A method for performing gas deposition comprising the steps of:
placing a substrate in a deposition chamber;
introducing a supply of plasma into an expansion chamber, the supply of plasma having a first pressure, the expansion chamber having a second pressure, the second pressure being lower than the first pressure;
passing the plasma to the deposition chamber through a plurality of ports, the deposition chamber being at a third pressure, the third pressure being lower than the second pressure; and
combining a reagent gas with the plasma.

13. The method of claim 12, wherein the plasma supply comprises an applicator, a gas supply connected to the applicator to supply a carrier gas to the applicator, and a microwave power supply configured to excite the carrier gas in the applicator to create a plasma.

14. The method of claim 12, wherein the first pressure is between approximately one half torr and approximately ten torr, and the second pressure is between approximately 0.1 torr and approximately two torr.

15. The method of claim 14, wherein the substrate is placed on a pedestal having a substantially planar first surface and the expansion chamber includes a substantially planar second surface, and further comprising the step of positioning the pedestal such that a distance between the first surface and the second surface results in substantially uniform deposition.

16. The method of claim 15, wherein the distance between the first surface and the second surface is between approximately ten centimeters and approximately 60 centimeters.

17. The method of claim 12, further comprising the step of supplying a reagent gas into each of the ports.

18. The method of claim 17, wherein the reagent gas is supplied through an orifice in a side wall in each of the ports.

19. The method of claim 13, further comprising the step of supplying a reagent gas into the expansion chamber.

20. The method of claim 19, wherein the supply includes a nozzle positioned in close proximity to an outlet of the applicator.

21. The method of claim 12, further comprising the step of positioning the expansion chamber over the deposition chamber.

22. The method of claim 12, further comprising the step of positioning the substrate such that it is at a height in the deposition chamber approximately equal to a height of at least one port formed in a sidewall wall of the deposition chamber and connected to a vacuum pump.

23. The method of claim 15, further comprising the step of rotating the pedestal.

24. A gas deposition apparatus comprising:
a microwave excited gas plasma supply, the plasma supply having a first pressure;
an expansion chamber positioned under and connected to the plasma supply to receive plasma therefrom, the expansion chamber being maintained a second pressure lower than the first pressure, the expansion chamber having a lower surface having a plurality of ports formed therein;
a reagent gas supply connected to supply a reagent gas into each of the plurality of ports through an orifice in a sidewall of the ports;
a deposition chamber positioned under the expansion chamber and in fluid communication therewith through the ports; and
a vacuum pump connected to the deposition chamber and operable to maintain the deposition chamber at a third pressure, the third pressure being lower than the second pressure.

25. A gas deposition apparatus comprising:
a microwave excited gas plasma supply, the plasma supply having a first pressure;
an expansion chamber positioned under and connected to the plasma supply to receive plasma therefrom, the expansion chamber being maintained a second pressure lower than the first pressure, the expansion chamber having a lower surface having a plurality of ports formed therein;
a reagent gas supply connected to supply a reagent gas to the expansion chamber;
a deposition chamber positioned under the expansion chamber and in fluid communication therewith through the ports; and
a vacuum pump connected to the deposition chamber and operable to maintain the deposition chamber at a third pressure, the third pressure being lower than the second pressure.
